(19) United States
(12) Patent Application Publication
(10) Pub. No.: US 2025/0210397 A1
(43) Pub. Date: Jun. 26, 2025

(54) MEMBER FOR SEMICONDUCTOR MANUFACTURING EQUIPMENT

(71) Applicant: NGK INSULATORS, LTD., Nagoya-City (JP)

(72) Inventors: Masaki ISHIKAWA, Handa-Shi (JP); Tatsuya KUNO, Nagoya-Shi (JP); Taro USAMI, Ginan-Cho (JP); Natsuki HIRATA, Nagoya-Shi (JP); Takahiro ANDO, Nagoya-Shi (JP)

(73) Assignee: NGK INSULATORS, LTD., Nagoya-City (JP)

(21) Appl. No.: 18/985,564

(22) Filed: Dec. 18, 2024

Related U.S. Application Data
(63) Continuation of application No. PCT/JP2023/045784, filed on Dec. 20, 2023.

(51) Int. Cl. H01L 21/683

(52) U.S. Cl. CPC H01L 21/6833

(57) ABSTRACT

A member for a semiconductor manufacturing equipment includes: a ceramic substrate having an upper surface on which a wafer is to be placed, and a lower surface; a plug placement hole; a dielectric plug embedded in the plug placement hole; a film covering at least a part of the lower surface of the dielectric plug and having a volume resistivity lower than that of the dielectric plug; a conductive base plate bonded to the lower surface of the ceramic substrate via a resin adhesive layer, a gas passage that passes through the base plate and the resin adhesive layer to supply gas to the to the gas passage portion of the dielectric plug, and a conductive connecting portion provided in the gas passage and having an upper end electrically connected to the film and a lower end electrically connected to the base plate.

### CROSS REFERENCE TO RELATED APPLICATIONS

The present invention claims the benefit of priority to International Patent Application No. PCT/JP2023/045784 filed on Dec. 20, 2023 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force. Some members are known that have a function of controlling the temperature of the wafer by flowing gas between the wafer placement surface and the wafer, which is the object to be adsorbed.

An example of a known member for semiconductor manufacturing equipment includes a ceramic substrate having an upper surface on which a wafer is placed and a lower surface opposite to the upper surface, a gas passage portion that vertically penetrates the dielectric substrate, and a conductive base plate bonded to the lower surface of the dielectric substrate.

In such a member for a semiconductor manufacturing equipment, a large potential difference from the wafer may occur, and discharge (insulation breakdown) may occur between the wafer and the base plate via the gas passage portion. For this reason, various techniques have been developed to suppress discharge.
Patent Literature 1 proposes a plug having a gas flow passage section that penetrates in flexion a dense main body portion in the thickness direction. It has also been proposed that at least a portion of the entire length of the gas flow passage section be made porous and insulating. Patent Literature 1 also describes that in the porous section, three-dimensionally (for example, in the form of a three-dimensional network) continuous pores within the porous section serve as gas flow paths, and therefore the effective flow path length within the gas flow path section is longer than when the entire gas flow path section is hollow, making it less likely for discharge to occur.

Patent Literature 2 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the ceramic dielectric substrate has a first main surface and a first hole portion located between the first main surface and the first porous portion; the first porous portion has a porous portion having a plurality of pores, and a first dense portion that is denser than the porous portion; and the ceramic dielectric substrate is configured such that when projected onto a plane perpendicular to a first direction from the base plate to the ceramic dielectric substrate, the first dense portion and the first hole portion overlap, but the porous portion and the first hole portion do not overlap.

According to Patent Literature 2, the electrostatic chuck is configured such that the first dense portion and the first hole portion overlap, so that the generated current tends to bypass the first dense portion, and therefore the distance through which the current flows (the conductive path) can be lengthened, making it difficult for electrons to be accelerated, and thus making it possible to suppress the occurrence of arc discharge.

Patent Literature 3 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the first porous portion has a plurality of sparse portions having a plurality of pores, and a dense portion having a density higher than the density of the sparse portion; each of the plurality of sparse portions extends in a first direction from the base plate toward the ceramic dielectric substrate; the dense portion is located among the plurality of sparse portions; the sparse portion has the holes and a wall portion provided among the holes; and in a second direction substantially perpendicular to the first direction, the minimum dimension of the wall portion is smaller than the minimum dimension of the dense portion.

According to Patent Literature 3, this electrostatic chuck has a first porous portion having sparse portions and dense portions extending in a first direction, and therefore it is possible to improve the mechanical strength (rigidity) of the first porous portion while ensuring resistance to arc discharge and gas flow rate.

Patent Literature 4 describes an invention that aims to provide a holding device that can control the temperature of an object with high accuracy while reducing the occurrence of abnormal discharge. Specifically, it describes a holding device comprising a ceramic substrate having a first surface that holds an object and a second surface located on the opposite side of the first surface; a base member disposed on the second surface side of the ceramic substrate, the base member having a third surface located on the opposite side of the ceramic substrate; and a bonding material disposed between the ceramic substrate and the base member; wherein (1) a passage is formed in the ceramic substrate and the base member to allow fluid to movably communicate between an outflow hole provided on the first surface and an inflow hole provided on the third surface, or (2) a passage is formed in the ceramic substrate to enable fluid to movably communicate between an outflow hole provided on the first surface and an inflow hole provided on the second surface; wherein the passage is provided with a porous ceramic region and the porous ceramic region comprises a sparse region and a dense region having a lower porosity than the sparse region and disposed closer to the first surface than the sparse region.

Patent Literature 5 discloses a wafer placement table in which an insulating first porous portion disposed within the through hole of the ceramic plate, and an insulating second porous portion fitted into a recess provided on the ceramic plate side of the base plate so as to face the first porous portion are provided. The gas supplied to the gas introduction path passes through the second porous portion and the first porous portion, flows into the space between the wafer placement surface and the wafer, and is used to cool the object. It is described that due to the presence of the first porous portion and the second porous portion, it is possible to suppress the occurrence of electrical discharge (arc discharge) caused by plasma upon processing wafers while ensuring the gas flow rate from the gas introduction passage to the wafer placement surface.

### PRIOR ART

### Patent Literature

[Patent Literature 1] Japanese Patent Application Publication No. 2022-119338
[Patent Literature 2] Japanese Patent Application Publication No. 2022-31333
[Patent Literature 3] Japanese Patent Application Publication No. 2019-165194
[Patent Literature 4] Japanese Patent Application Publication No. 2022-176701
[Patent Literature 5] Japanese Patent Application Publication No. 2020-72262

### SUMMARY OF THE INVENTION

As described above, various techniques have been proposed for the member for a semiconductor manufacturing equipment to improve the structure of the gas passage portion that vertically penetrates the ceramic substrate in order to suppress the electrical discharge that occurs between the wafer and the base plate. However, it is believed that developing a technique for suppressing discharge using an approach different from these is significant for the development of technology for the member for a semiconductor manufacturing equipment. In particular, there is still room for improvement in the technology for suppressing the discharge that occurs near the bonding portion between the ceramic substrate and the base plate in the gas passage portion that vertically penetrates the ceramic substrate.

In view of the above circumstances, an object of an embodiment of the present invention is to provide a member for a semiconductor manufacturing equipment that helps suppress discharge that occurs near the bonding portion between the ceramic substrate and the base plate in the gas passage portion that vertically penetrates the ceramic substrate.

The present inventors have made extensive studies to solve the above problems, and have created the present invention as exemplified below.

### Aspect 1

A member for a semiconductor manufacturing equipment, comprising:
a ceramic substrate comprising an upper surface on which a wafer is to be placed, and a lower surface opposite to the upper surface,
a plug placement hole that vertically penetrates the ceramic substrate,
a dielectric plug embedded in the plug placement hole, the dielectric plug comprising a lower surface and a gas passage portion penetrating the dielectric plug,
a first film covering at least a part of the lower surface of the dielectric plug and made of a material having a volume resistivity lower than that of a material constituting the dielectric plug,
a conductive base plate bonded to the lower surface of the ceramic substrate via a resin adhesive layer,
a gas passage that passes through the base plate and the resin adhesive layer to supply gas to the gas passage portion of the dielectric plug, and
a conductive connecting portion provided in the gas passage, the conductive connecting portion comprising an upper end electrically connected to the first film and a lower end electrically connected to the base plate;
wherein at least a part of the first film is in contact with the resin adhesive layer, and/or at least a part of the lower surface of the ceramic substrate is covered with a second film made of a material having a volume resistivity lower than that of a material constituting the ceramic substrate, and at least a part of the second film is in contact with the resin adhesive layer and also in contact with the first film.

### Aspect 2

The member for a semiconductor manufacturing equipment according to aspect 1, wherein at least a part of the first film is in contact with the resin adhesive layer.

### Aspect 3

The member for a semiconductor manufacturing equipment according to aspect 1 or 2, wherein at least a part of the lower surface of the ceramic substrate is covered with the second film made of a material having a volume resistivity lower than that of the material constituting the ceramic substrate, and at least a part of the second film is in contact with the resin adhesive layer and also in contact with the first film.

### Aspect 4

The member for a semiconductor manufacturing equipment according to any one of aspects 1 to 3, wherein the connecting portion comprises a member having elasticity, and the member having elasticity is compressed by pressure of the first film on the lower surface of the dielectric plug.

### Aspect 5

The member for a semiconductor manufacturing equipment according to any one of aspects 1 to 4, wherein the connecting portion comprises a member having elasticity, and the member having elasticity is compressed by pressure of the second film on the lower surface of the ceramic substrate.

### Aspect 6

The member for a semiconductor manufacturing equipment according to any one of aspects 1 to 5, wherein the material constituting the dielectric plug and the material constituting the ceramic substrate each contain one of more selected from aluminum oxide, aluminum nitride, quartz, and zirconia.

### Aspect 7

The member for a semiconductor manufacturing equipment according to any one of aspects 1 to 6, wherein the first film on the lower surface of the dielectric plug comprises metal, carbon, conductive ceramic, or a composite material containing two or more of them.

### Aspect 8

The member for a semiconductor manufacturing equipment according to any one of aspects 1 to 7, wherein the second film on the lower surface of the ceramic substrate comprises metal, carbon, conductive ceramic, or a composite material of two or more of them.

### Aspect 9

The member for a semiconductor manufacturing equipment according to any one of aspects 1 to 8, wherein the dielectric plug is an inorganic dielectric plug having a dense outer peripheral surface, and is embedded in the plug placement hole such that the outer peripheral surface directly fits an inner peripheral surface of the plug placement hole.

### Aspect 10

The member for a semiconductor manufacturing equipment according to any one of aspects 1 to 9, wherein an inner periphery of a penetrated portion of the resin adhesive layer that defines the gas passage is configured such that the gas passage becomes wider upward.

### Aspect 11

The member for a semiconductor manufacturing equipment according to aspect 9, wherein the inner peripheral surface of the plug placement hole that fits the dense outer peripheral surface of the dielectric plug is dense.

A member for a semiconductor manufacturing equipment according to an embodiment of the present invention is effective in suppressing discharge occurring between the wafer and the base plate, in particular, discharge occurring near the bonding portion between the ceramic substrate and the base plate in the gas passage portion that vertically penetrates the ceramic substrate.

### BRIEF DESCRIPTION OF THE DRAWINGS

FIG. 1 is a schematic plan view of a member for a semiconductor manufacturing equipment according to an embodiment of the present invention.

FIG. 2A is an example of a schematic cross-sectional view taken along line A-A in FIG. 1.

FIG. 2B is another example of a schematic cross-sectional view taken along line A-A in FIG. 1.

FIG. 2C is a further example of a schematic cross-sectional view taken along line A-A in FIG. 1.

FIGS. 3A to 3G are manufacturing process diagrams of a member for a semiconductor manufacturing equipment according to an embodiment of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal plane with a base plate facing downward, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of Member for Semiconductor Manufacturing Equipment

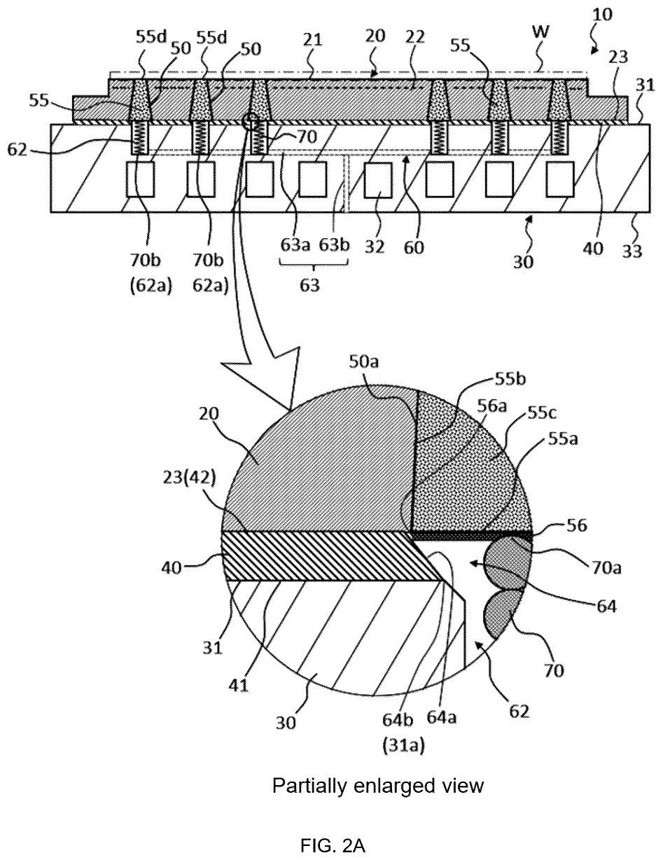

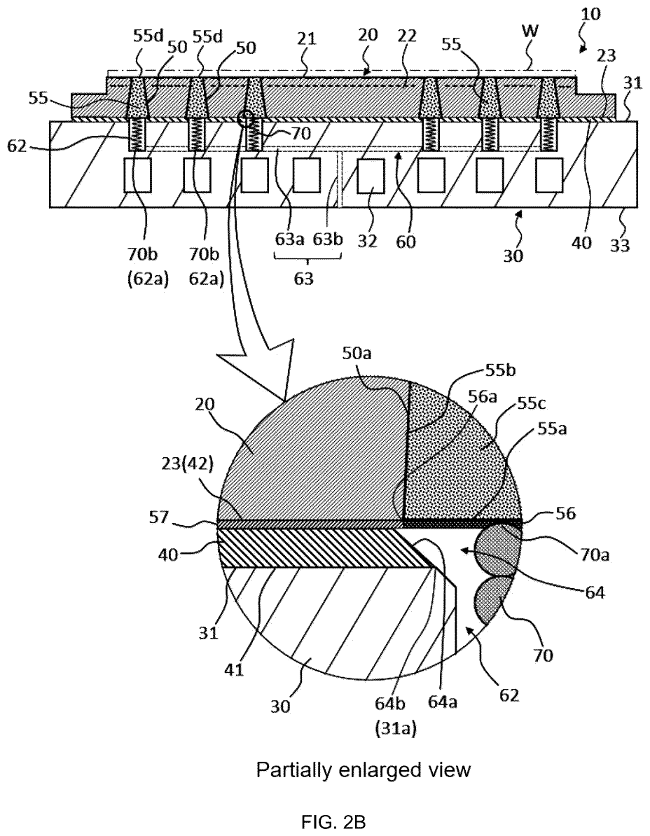

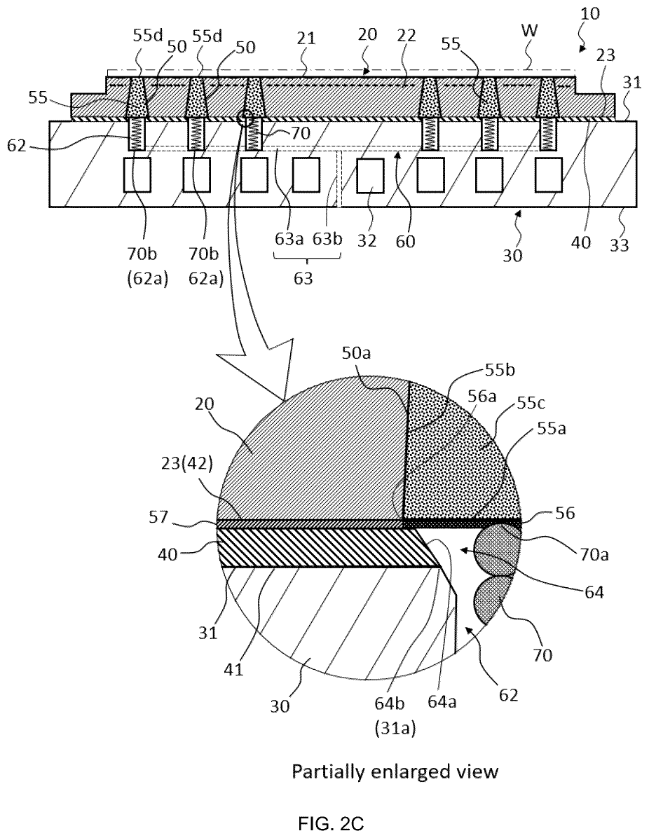

Referring to FIGS. 2A, 2B and 2C, a member 10 for a semiconductor manufacturing equipment according to an embodiment of the present invention comprises:
a ceramic substrate 20 comprising an upper surface 21 on which a wafer is to be placed, and a lower surface 23 opposite to the upper surface 21,
a plug placement hole 50 that vertically penetrates the ceramic substrate 20,
a dielectric plug 55 embedded in the plug placement hole 50, the dielectric plug 55 comprising a lower surface 55a and a gas passage portion 55c penetrating the dielectric plug 55,
a first film 56 covering at least a part of the lower surface 55a of the dielectric plug 55 and made of a material having a volume resistivity lower than that of a material constituting the dielectric plug 55,
a conductive base plate 30 bonded to the lower surface 23 of the ceramic substrate 20 via a resin adhesive layer 40,
a gas passage 60 that passes through the base plate 30 and the resin adhesive layer 40 to supply gas to the gas passage portion 55c of the dielectric plug 55, and
a conductive connecting portion 70 provided in the gas passage 60, the conductive connecting portion 70 comprising an upper end 70a electrically connected to the first film 56 and a lower end 70b electrically connected to the base plate 30.

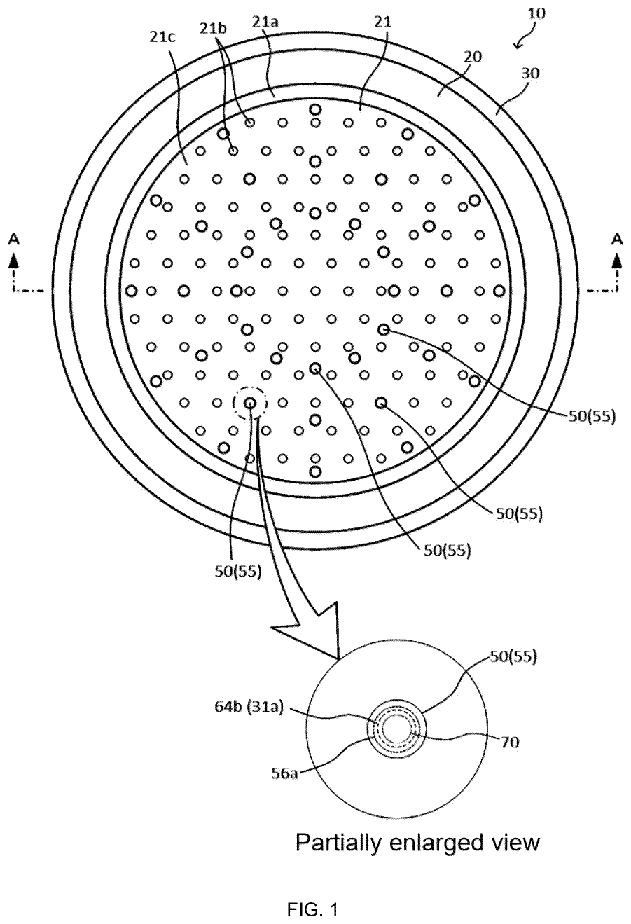

The ceramic substrate 20 may be, for example, a circular plate (for example, 300 to 400 mm in diameter and 1 to 5 mm in thickness) made of ceramics such as sintered alumina or sintered aluminum nitride. An upper surface 21 of the ceramic substrate 20 has a wafer placement surface for placing a wafer W. The ceramic substrate 20 has an electrode 22 therein. As shown in FIG. 1, on the upper surface 21 of the ceramic substrate 20, an annular seal band 21a is formed along the outer edge, and a plurality of small protrusions 21b are formed on the entire surface inside the seal band 21a. Although the shape of the small protrusion 21b is not limited, it can be, for example, a cylinder, a prism, or the like. It is preferable that the seal band 21a and the small protrusions 21b have the same height, and the height is, for example, 5 to 100 μm, and typically 10 to 30 μm. The electrode 22 is a planar electrode used as an electrostatic electrode, and is connected to an external DC power source via a power supply member (not shown). A low-pass filter may be placed in the middle of the power supply member. The power supply member is electrically insulated from the resin adhesive layer 40 and the base plate 30. When a DC voltage is applied to this electrode 22, the wafer W is adsorbed and fixed to the wafer placement surface (specifically, the upper surface of the seal band 21a and the upper surface of the small protrusion 21b) by electrostatic attraction force, and when the application of the DC voltage is released, the adsorption and fixation of the wafer W to the wafer placement surface is released. In addition, the portion of the upper surface 21 of the dielectric substrate 20 where the seal band 21a and the small projections 21b are not provided is referred to as a reference surface 21c.

As the electrode 22, a heater electrode (resistance heating element) may be incorporated instead of or in addition to the electrostatic electrode. In that case, a heater power source is connected to the heater electrode. One layer of electrode may be provided inside the ceramic substrate 20, or two or more layers which are spaced apart from each other may be provided inside the dielectric substrate 20.

The conductive base plate 30 is a circular plate (having a diameter equal to or larger than that of the ceramic substrate 20) with good electrical conductivity and thermal conductivity. Inside the base plate 30, a refrigerant passage 32 through which refrigerant circulates may be formed. The refrigerant flowing through the refrigerant passage 32 is preferably liquid and preferably electrically insulating. Examples of the electrically insulating liquid include fluorine-based inert liquids. The refrigerant passage 32 can be formed, for example, in a single stroke across the entire base plate 30 from one end (inlet) to the other end (outlet) in a plan view. A supply port and a recovery port of an external refrigerant device (not shown) are connected to the one end and the other end of the refrigerant passage 32, respectively. The refrigerant supplied from the supply port of the external refrigerant device to the one end of the refrigerant passage 32 passes through the refrigerant passage 32 and then returns from the other end of the refrigerant passage 32 to a recovery port of the external refrigerant device, and after the temperature has been adjusted, the refrigerant is again supplied to the one end of the refrigerant passage 32 from the supply port. The base plate 30 is connected to a radio frequency (RF) power source and can also be used as an RF electrode.

Examples of the material of the base plate 30 include metal materials and composite materials of metal and ceramics. Examples of the metal material include Al, Ti, Mo, W, and alloys thereof. Examples of composite materials of metal and ceramics include metal matrix composites (MMC) and ceramic matrix composites (CMC). Specific examples of such composite materials include materials containing Si, SiC, and Ti (also referred to as SiSiCTi), materials in which porous SiC is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a coefficient of thermal expansion close to that of the material for the dielectric substrate 20. For example, when the dielectric substrate 20 is made of alumina, the base plate is preferably made of SiSiCTi or AlSiC.

As shown in FIGS. 2A, 2B and 2C, the upper surface 31 of the base plate 30 is bonded to the lower surface 23 of the ceramic substrate 20 via a resin adhesive layer 40. The resin adhesive layer 40 can be composed of, for example, a cured product of a silicone resin-based adhesive, an epoxy resin-based adhesive, an acrylic resin-based adhesive, or a urethane resin-based adhesive. The uncured adhesive is preferably provided in the form of a resin adhesive sheet. There is no particular limitation on the curing method, but examples include a heat curing method. For the reason of increasing the adhesive strength, a method of curing while applying heat and pressure (for example, autoclave) is preferable. In order to increase the uniformity of the thickness of the resin adhesive layer 40, a spacer (not shown) may be placed between the upper surface 31 of the base plate 30 and the lower surface 23 of the ceramic substrate 20.

The plug placement hole 50 is a hole that vertically penetrates the ceramic substrate 20, as shown in FIGS. 2A, 2B and 2C. The plug placement hole 50 is a gas passage from the lower surface 23 of the ceramic substrate 20 to the reference surface 21c of the upper surface 21. The opening diameter (if the cross section of the plug placement hole is not circular, it means the equivalent circle diameter.) of the plug placement hole 50 in the horizontal direction is not limited, but may be within the range of 1 to 5 mm, typically within the range of 3 to 4 mm, at any height position. In the present embodiment, the diameter of the plug placement hole 50 decreases from bottom to top, and the inner peripheral surface 50a of the plug placement hole 50 is a tapered surface. This reduces the possibility that the dielectric plug 55 will move upward, weakening its contact with the connecting portion 70, or be pulled out of the ceramic substrate 20, when an upward force is applied from the connecting portion 70 to the dielectric plug 55.

As shown in FIG. 1, a plurality of (here, the number is 36) plug placement holes 50 are provided. The plug placement holes 50 may have, for example, a space in the shape of a truncated cone or a truncated pyramid. A dielectric plug 55 is embedded in the plug placement hole 50. The plug 55 has a gas passage portion 55c penetrating inside the plug 55. In one embodiment, the gas passage portion 55c has one opening on the lower surface 55a of the plug 55 and the other opening on the upper surface 55d of the plug 55, and penetrating inside the plug 55 in the vertical direction. In another embodiment, the gas passage portion 55c has one opening in the lower surface 55a of the plug 55 and the other opening in the outer peripheral surface 55b, and penetrates the inside of the plug 55. Here, the dielectric plug 55 is fixed in a state where it is filled in the plug placement hole 50. There is no particular limitation on the fixing method, but for example, the dielectric plug 55 may be fixed such that the outer peripheral surface 55b of the dielectric plug 55 and the inner peripheral surface 50a of the plug placement hole 50 are directly fitted together. The method for direct fitting includes a method of embedding the dielectric plug 55 in the plug placement hole 50 by press fitting. The dielectric plug 55 preferably has an outer shape that is the same as that of the plug placement hole 50 (for example, a truncated cone or pyramid shape). In this case, in order to obtain the desired fixing strength, it is preferable that the horizontal cross-sectional diameter at any height position of the dielectric plug 55 be slightly larger (for example, about 5 to 20 μm in equivalent circle diameter) than the cross-sectional diameter of the plug placement hole 50 at the same height position. In addition, another method for direct fitting is to screw a male thread provided on the outer peripheral surface 55b of the dielectric plug 55 into a female thread provided on the inner peripheral surface 50a of the plug placement hole 50. Furthermore, the outer peripheral surface 55b of the dielectric plug 55 and the inner peripheral surface 50a of the plug placement hole 50 may be bonded together via an adhesive. However, when an adhesive is used for fixing, the adhesive is likely to wear out or deteriorate, resulting in a decrease in the fixing strength of the plug. Therefore, it is preferable to employ a direct fitting method. If the two are directly fitted, no gap will be created between the dielectric plug 55 and the plug placement hole 50 caused by deterioration due to corrosion or erosion of the adhesive. Therefore, there is an advantage that discharge and falling off of the plug 55 due to deterioration of the adhesive can be suppressed.

The height position of the upper surface 55d of the dielectric plug 55 is not limited, and may be set to the same height as the reference surface 21c of the ceramic substrate 20 or may be set to a different height. However, it is preferable that the height position of the upper surface 55d of the dielectric plug 55 be the same as the reference surface 21c. If the top surface of the dielectric plug 55 is made lower than the reference surface 21c, it is preferable to place it at a lower position within a range of 0.5 mm or less (preferably 0.2 mm or less, and more preferably 0.1 mm or less) in order to suppress the occurrence of discharge. When the upper surface of the dielectric plug 55 is higher than the reference surface 21c, there is no particular restriction as long as it is lower than the upper surfaces of the small protrusions 21b and the outflow of gas from the dielectric plug 55 is not impeded.

The height position of the lower surface 55a of the dielectric plug 55 is not particularly limited as long as at least a portion of the first film 56 can be in contact with the resin adhesive layer 40. Therefore, it may be at the same height as the lower surface 23 of the ceramic substrate 20 or at a different height. For example, the lower surface 55a of the dielectric plug 55 may protrude downwardly from the lower surface 23 of the ceramic substrate 20, or the lower surface 55a of the dielectric plug 55 may be located above the lower surface 23 of the ceramic substrate 20.

The material constituting the dielectric plug 55 is preferably an inorganic dielectric, for example a ceramic, and in a preferred embodiment, may contain one or more selected from aluminum oxide, aluminum nitride, quartz, and zirconia. The material may be composed of only one or two selected from aluminum oxide and aluminum nitride, excluding impurities. For example, a plurality of plugs made of different materials can be stacked vertically. In this case, the plugs on the upper side can be made of ceramics with a higher volume resistivity than the plugs on the lower side, and the plugs on the lower side can be brought into contact with the base plate or the connecting portion, thereby lowering the potential of the plugs on the lower side and suppressing discharge on the lower side, where the space is large and discharge is likely to occur. Specifically, the plug on the upper side may be made of aluminum oxide and the plug on the lower side may be made of SiC, and these may be disposed in this order in the plug placement hole.

From the viewpoint of maintaining the fixing strength of the dielectric plug 55, it is preferable that the difference in thermal expansion coefficient between the dielectric plug 55 and the ceramic substrate 20 be small. Therefore, it is preferable that the material constituting the plug 55 and the material constituting the ceramic substrate 20 both contain one or more selected from aluminum oxide and aluminum nitride, and it is more preferable that the material compositions be the same.

It is preferable that the dielectric plug 55 have a dense outer peripheral surface 55b. If the dielectric plug 55 has a dense outer peripheral surface 55b, particularly when the dielectric plug 55 is directly fitted into the inner peripheral surface 50a of the plug placement hole 50, a sufficient frictional force acts, thereby increasing the fixing strength of the dielectric plug 55. The fact that the outer peripheral surface 55b is dense means that the porosity of the outer peripheral surface 55b is 10% or less. The porosity of the outer peripheral surface 55b is preferably 5% or less, more preferably 1% or less.

The porosity of the outer peripheral surface 55b is measured by the following method. The dielectric plug 55 is cut such that a cross section perpendicular to the outer peripheral surface 55b of the dielectric plug 55 is exposed. Next, a 100 μm thick portion from the outer peripheral surface 55b of the cross section is observed using a scanning electron microscope (SEM) at a magnification of 3000 times in approximately 2200 μm², and then the area ratio of pores confirmed in the thick portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pore portions to the total area (total area of the solid portions and the pore portions) is determined. The same measurements are performed at five locations on the same dielectric plug 55, and the average value of the measurements at five locations is taken as the porosity of the outer peripheral surface 55b of the dielectric plug 55.

In particular, when the outer peripheral surface 55b of the dielectric plug 55 is directly fitted into the inner peripheral surface 50a of the plug placement hole 50, it is preferable that the inner peripheral surface 50a of the plug placement hole 50 be also dense in order to increase the fixing strength due to friction of the dielectric plug 55. The fact that the inner peripheral surface 50a is dense means that the porosity of the inner peripheral surface 50a is 5% or less. The porosity of the inner peripheral surface 50a is preferably 1% or less, and more preferably 0.5% or less.

Since the inner peripheral surface 50a is a part of the ceramic substrate 20, as used herein, the porosity value of the ceramic substrate 20 is regarded as the porosity of the inner peripheral surface 50a. The porosity of the ceramic substrate 20 is defined as the open porosity measured according to JIS R1634: 1998, and the measured value is the average value of the open porosity for five samples taken from the ceramic substrate 20 without bias.

The dielectric plug 55 has a gas passage portion 55c penetrating the inside of the dielectric plug 55. In one embodiment, the gas passage portion 55c has a structure that allows gas flowing in from a lower surface 55a of the dielectric plug 55 to flow through the gas passage portion 55c and to flow out from an upper surface 55d of the dielectric plug 55. For example, the gas passage portion 55c may be formed by forming one or more gas flow passages that vertically penetrate a dense material that does not allow gas flow. In this case, the gas flowing in from the lower surface 55a of the dielectric plug 55 flows through the gas flow passage and flows out from the upper surface 55 d of the dielectric plug 55. The gas passage may be constructed of a straight line, a curved line, or a combination of both, but from the viewpoint of suppressing discharge, it is preferable to have a shape such that the length of the gas passage is longer than the length of the dielectric plug 55 in the vertical direction, for example, a curved shape such as a spiral shape or a zigzag shape. The fact that the dielectric plug 55 is dense means that the porosity of the dielectric plug 55 is 5% or less. The porosity of the dielectric plug 55 is preferably 1% or less, and more preferably 0.5% or less.

The porosity of the dielectric plug 55 is measured by the following method. The dielectric plug 55 is cut such that a cross section passing through the central axis extending in the vertical direction of the dielectric plug 55 is exposed. Next, a portion of the cross section excluding the gas passage is observed using a scanning electron microscope (SEM) at a magnification of 3000 times in approximately 2200 μm², and the area ratio of pores confirmed in the portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pore portions to the total area (total area of the solid portions and the pore portions) is determined. The same measurements are performed at five locations on the same dielectric plug 55, and the average value of the measurements at five locations is taken as the porosity of the dielectric plug 55.

As a method of providing a gas passage in the dielectric plug 55 which is dense, mention may be made to a method of firing a formed body formed using additive manufacturing technology such as a 3D printer, and a method of firing a formed body formed by mold casting using a master mold produced by a lost-wax method, for example. Mold casting is disclosed in, for example, Japanese Patent No. 7144603.

In addition, it is possible to form a gas passage portion 55c by providing a porous portion in the dielectric plug 55. When the gas passage portion 55c is porous, the gas flowing in from the lower surface 55a of the dielectric plug 55 flows through the gas passage 55c formed by a large number of continuous pores, and flows out from the upper surface 55d of the dielectric plug 55. Since three-dimensional (for example, three-dimensional network) continuous pores that exist within the porous material serve as gas passages, the substantial passage length within the gas passage portion 55c becomes longer compared to the case where the gas passage portion 55c is hollow, and an effect that electric discharge is less likely to occur can be obtained. The porous gas passage portion can be formed on the inner peripheral side of the dense outer peripheral surface. It is also possible to further form one or more gas passages within the porous gas passage portion.

Therefore, the gas passage portion 55c may be hollow or porous, and it is preferable that at least a part of the gas passage portion 55c be porous. The fact that the gas passage portion 55c is hollow means that the porosity of the gas passage portion 55c is 100%. The fact that the gas passage portion 55c is porous means that the porosity of the gas passage portion 55c is more than 5% and less than 100%. The porosity of the gas passage portion 55c is preferably large in order to reduce the airflow resistance, and therefore the porosity of the gas passage portion 55c is preferably 10% or more, and more preferably 40% or more. On the other hand, the porosity of the gas passage portion 55c is preferably 50% or less in order to increase the flow path length and ensure the structural strength of the dielectric plug 55. Therefore, the porosity of the gas passage portion 55c is preferably, for example, 10% or more and 50% or less, and more preferably 40% or more and 50% or less.

The porosity of the gas passage portion 55c is measured by mercury porosimetry method (JIS R1655: 2003).

The porosity of the dielectric plug 55 and the ceramic substrate 20 can be controlled, for example, by adjusting the content of the pore-forming material in the raw material composition before producing by firing the ceramics which they are made of. For example, in order to make the outer peripheral surface of the dielectric plug denser, the amount of pore-forming material near the outer peripheral surface may be partially reduced or may not be used. Furthermore, in order to make the inner peripheral surface of the plug placement hole denser, the amount of pore-forming material near the inner peripheral surface may be partially reduced or may not be used.

The lower surface 55a of the dielectric plug 55 is covered with a first film 56 made of a material having a volume resistivity lower than the material constituting the dielectric plug 55. The first film 56 may cover a part of the lower surface 55a of the dielectric plug 55 or may cover the entire lower surface 55a. This is because the first film 56 is thin and allows gas to pass through it regardless of whether it is dense or porous. The volume resistivity of the material constituting the first film 56 at 20° C. is preferably 74×10⁻⁸ Ω·m or less, more preferably 60×10⁻⁸ Ω·m or less, and even more preferably 53×10⁻⁸ Ω·m or less. Although there is no particular lower limit to the volume resistivity of the material constituting the first film 56, from the viewpoint of availability, it is preferably 2×10⁻⁸ Ω·m or more, preferably 3×10⁻⁸ Ω·m or more, and preferably 10×10⁻⁸ Ω·m or more, at 20° C. Therefore, the volume resistivity of the material constituting the first film 56 is preferably, for example, 2×10⁻⁸ Ω·m or more and 74×10⁻⁸ Ω·m or less, more preferably 3×10⁻⁸ Ω·m or more and 60×10⁻⁸ Ω·m or less, and even more preferably 10×10⁻⁸ Ω·m or more and 53×10⁻⁸ Ω·m or less, at 20° C. The volume resistivity of the material constituting the first film 56 is measured by a method according to JIS C2525: 1999.

From the viewpoint of suppressing discharge, in addition to the lower surface 55a of the dielectric plug 55, it is preferable that the lower surface 23 of the ceramic substrate 20 be also covered with a second film 57 made of a material having a volume resistivity lower than the material constituting the ceramic substrate 20. In addition, it is preferable that at least a portion of the second film 57 be in contact with the resin adhesive layer 40 and also with the first film 56 (see FIG. 2B). In this case, discharge can be suppressed even if at least a portion of the first film 56 is not in contact with the resin adhesive layer 40. Of course, the resin adhesive layer 40 may contact both the first film 65 and the second film 57 as shown in FIG. 2C. The volume resistivity of the material constituting the second film 57 at 20° C. is preferably 74×10⁻⁸ Ω·m or less, more preferably 60×10⁻⁸ Ω·m or less, and even more preferably 53×10⁻⁸ Ω·m or less. Although there is no particular lower limit to the volume resistivity of the material constituting the second film 57, from the viewpoint of availability, it is preferably 2×10⁻⁸ Ω·m or more, preferably 3×10⁻⁸ Ω·m or more, and more preferably 10×10⁻⁸ Ω·m or more, at 20° C. Therefore, the volume resistivity of the material constituting the second film 57 is preferably, for example, 2×10⁻⁸ Ω·m or more and 74×10⁻⁸ Ω·m or less, more preferably 3×10⁻⁸ Ω·m or more and 60×10⁻⁸ Ω·m or less, and even more preferably 10×10⁻⁸ Ω·m or more and 53×10⁻⁸ Ω·m or less, at 20° C. The volume resistivity of the material constituting the first film 56 is measured by a method according to JIS C2525: 1999.

As shown in FIG. 2A, when the vicinity of the plug placement hole 50 on the lower surface 23 of the ceramic substrate 20 is covered with the resin adhesive layer 40, since the lower surface 23 of the ceramic substrate 20 is not exposed, the second film 57 may not be present. However, depending on the processing accuracy, the resin adhesive layer 40 may not sufficiently cover the lower surface 23 of the ceramic substrate 20, resulting in exposure of the vicinity of the plug placement hole 50 on the lower surface 23 of the ceramic substrate 20. Furthermore, there are cases where at least a portion of the first film 56 does not come into contact with the resin adhesive layer 40. For this reason, as shown in FIG. 2B, by covering the vicinity of the plug placement hole 50 on the lower surface 23 of the ceramic substrate 20 in advance with a film 57, the risk of discharge can be reduced. The film 57 may cover a part of or the entire lower surface 23 of the ceramic substrate 20. However, taking into account the processing accuracy of the resin adhesive layer 40, it is preferable from the viewpoint of cost-effectiveness that the film 57 be formed to an extent that the lower surface 23 of the ceramic substrate 20 does not expose (for example, when the ceramic substrate 20 is observed from the side of the lower surface 23, a distance of 1 to 10 mm in the direction perpendicular to each tangent line at the inner periphery of the plug placement hole 50).

The average thickness of the first film 56 covering the lower surface 55a of the dielectric plug 55 and the film 57 covering the lower surface 23 of the ceramic substrate 20 is preferably 0.5 μm or more, more preferably 1 μm or more, and even more preferably 20 μm or more, in order to reduce the contact resistance. In addition, the average thickness of first film 56 and second film 57 is preferably equal to or less than the thickness of the resin adhesive layer 40 so as not to protrude above or below resin adhesive layer 40, and is more preferably 100 μm or less, and is even more preferably 60 μm or less so as not to block the gas inlet of the plug. Therefore, the average thickness of the first film 56 and the second film 57 is, for example, preferably 0.5 μm or more and 100 μm or less, more preferably 1 μm or more and 60 μm or less, and even more preferably 20 μm or more and 50 μm or less.

The average thickness of the first film 56 and the second film 57 is measured by, for example, cross-sectional observation using a SEM. Specifically, the thickness of the film is measured at three points at equal intervals of 5 μm per field of view using a scanning electron microscope (SEM) at a magnification of 3000 times, and the average film thickness per field of view is calculated. The same measurement is performed for five arbitrary fields of view, and the average film thickness in the five fields of view is taken as the measured value.

If the first film 56 and/or the second film 57 are electrically connected to the base plate 30 via a conductive connecting portion 70, which will be described later, the potential can be reduced to approximately the same as that of the base plate 30. Since the potential of the base plate is usually the ground (GND), the potential at the lower surface 55a of the dielectric plug 55 can be dropped to the ground, so that the occurrence of discharge near the lower surface 55a of the dielectric plug 55 can be suppressed.

The materials that constitute the first film 56 and the second film 57 can be metals, carbon, conductive ceramics, or composite materials of metals and ceramics. Thus, in one embodiment, the first film 56 and the second film 57 comprise metal, carbon, conductive ceramic, or a composite material of two or more of them. As the metal, mention can be made to a simple metal selected from Au, Ag, Al, Ti, and Mo, or an alloy containing one or more of these metals, stainless steel such as SUS316L, and highly corrosion-resistant Ni alloys such as Hastelloy. As the carbon, mention can be made to diamond-like carbon (DLC), and the like. As the conductive ceramic, mention can be made to SiC, SiSiC, or the like. In addition to the inorganic materials, organic matter may remain in the first film 56 and the second film 57. As the organic matter, mention can be made to acrylic resin and epoxy resin. Further, in addition to the metal, inorganic materials such as glass may also be contained.

As a method for forming the first film 56 on the lower surface 55a of the dielectric plug 55 and forming the second film 57 on the lower surface 23 of the ceramic substrate 20, for example, mention can be made to thermal spraying, CVD method, PVD method (for example, sputtering, vacuum deposition, ionization deposition, ion beam), dipping, and stamping.

Referring to FIGS. 2A, 2B and 2C, the gas passage 60 for supplying gas to the gas passage portion 55c of the dielectric plug 55 through the base plate 30 and the resin adhesive layer 40 comprises, for example, an adhesive layer penetrating portion 64 that penetrates the resin adhesive layer 40 in the vertical direction to define a gas passage 60, a gas distribution path 62 that communicates with the adhesive layer penetrating portion 64 and extends downward from the upper surface 31 of the base plate 30, and a gas supply path 63 that communicates with the gas distribution path 62 to supply gas to the gas distribution path 62. There is no particular limitation on the configuration of the gas supply path 63. For example, one or more ring portions 63a whose passage extends concentrically with the base plate 30 in a plan view, and one or more gas introduction portions 63b to supply the gas introduced from the lower surface 33 of the base plate 30 to the ring portion 63a may be provided. Further, the gas passages 60 may be configured to communicate with the plug placement holes 50 in a one-to-one correspondence with each other. Other auxiliary passages (not shown) may also be provided.

As shown in FIGS. 2A, 2B and 2C, at least a part of the film 56 covering the lower surface 55a of the dielectric plug 55 is in contact with the resin adhesive layer 40. There are no particular limitations on the location of contact, but for example, it may be in contact with the inner periphery 64a of the adhesive layer penetrating portion 64. By having the first film 56 in contact with the resin adhesive layer 40, or by having the second film 57 in contact with both the first film 56 and the resin adhesive layer 40, it is possible to suppress the occurrence of discharge between the lower surface 55a of the dielectric plug 55 and the resin adhesive layer 40. This is because the resin adhesive layer 40 is electrically conductive to the base plate 30. As long as the first film 56 is in contact with the resin adhesive layer 40, there are no particular limitations on the structure of the adhesive layer penetrating portion 64, but it is preferable that the adhesive layer penetrating portion 64 be arranged such that there is a portion that overlaps with the first film 56 when seen through virtually from above, since this makes it easier for the two to come into contact. In the present embodiment, as can be seen from the partially enlarged view of FIG. 1 and FIG. 2A, when seen through virtually from above, the location 64b of the inner periphery 64a of the adhesive layer penetrating portion 64 having the smallest opening diameter (in the present embodiment, the lower end of the adhesive layer penetrating portion 64) is located within the area defined by the outer periphery 56a of the first film 56 covering the lower surface 55a of the dielectric plug 55.

Furthermore, as can be understood from the partially enlarged view of FIG. 1 and FIG. 2A, when seen through virtually from above, the inner periphery 31a of the gas distribution path 62 on the upper surface 31 of the base plate 30 is located within the area defined by the outer periphery 56a of the first film 56 covering the lower surface 55a of the dielectric plug 55. This allows the diameter of the adhesive layer penetrating portion 64 to be reduced, making it easier for at least a portion of the first film 56 covering the lower surface 55a of the dielectric plug 55 to come into contact with the resin adhesive layer 40.

As shown in FIGS. 2A, 2B and 2C, the adhesive layer penetrating portion 64 may be a hole that penetrates the resin adhesive layer 40 in the vertical direction, and is a gas passage that extends from the lower surface 41 of the resin adhesive layer 40 to the upper surface 42 of the resin adhesive layer 40. In the present embodiment, a plurality of adhesive layer through-holes 64 (36 in this example) are provided and are arranged in one-to-one correspondence with the plug arrangement holes 50.

The inner periphery 64a of the adhesive layer penetrating portion 64 may extend in the vertical direction, but is preferably configured such that the gas passage becomes wider upward, as shown in FIGS. 2A, 2B and 2C. This creates an inclined surface on the inner periphery 64a of the adhesive layer penetrating portion 64. When the base plate 30 and the ceramic substrate 20 are bonded via the resin adhesive layer 40, there is a risk that the resin adhesive layer 40 protrudes significantly toward the lower surface 55a of the dielectric plug 55, covering the gas introduction port on the lower surface 55a and reducing the gas flow rate flowing through the lower surface 55a of the dielectric plug 55. However, with this configuration, the risk that the resin adhesive layer 40 will cover the gas introduction port on the lower surface 55a of the dielectric plug 55 can be reduced.

The conductive connecting portion 70 has an upper end 70a electrically connected to the first film 56 and a lower end 70b electrically connected to the base plate 30, and is provided in the gas passage 60. Typically, the upper end 70a of the conductive connecting portion 70 contacts the first film 56, and the lower end 70b of the conductive connecting portion 70 contacts the base plate 30. The connecting portion 70 installed at one location may be composed of a single member or may be composed of multiple members.

In the present embodiment, the connecting portion 70 is provided as a separate body from the base plate 30, and the lower surface of the connecting portion 70 is in contact with the base plate 30. More specifically, the connecting portion 70 is provided across the inside of the adhesive layer penetrating portion 64 of the gas passage 60 and the inside of the gas distribution path 62, and is in contact with the base plate 30 at the bottom surface 62a of the gas distribution path 62. The connecting portion 70 is in contact with the base plate 30 and is thereby electrically connected to the base plate 30. A plurality of connecting portions 70 (36 in this example) are provided, and are arranged in one-to-one correspondence with the dielectric plugs 55. In the present embodiment, the connecting portion 70 is a coil spring having a circular shape in a plan view. The connecting portion 70 may be an integral member with the base plate 30, not a separate body from the base plate 30. For example, the connecting portion 70 may be a part of the base plate 30. In this case, the connecting portion 70 can be formed as a protrusion provided on the upper surface of the bottom surface 62a of the gas distribution path 62.

The connecting portion 70 may be configured so as not to block the flow of gas passing through the gas passage 60, and the gas does not have to be able to pass through the inside of the connecting portion 70. In addition, the connecting portion 70 may have a structure that allows gas to pass through the inside thereof. In this case, the gas in the gas passage 60 can pass through the inside of the connecting portion 70 and flow into the plug placement hole 50. Examples of materials through which gas can pass include a conductive mesh, a mass of conductive fibers, and a conductive porous body.

It is desirable that the connecting portion 70 be made of a material having a volume resistivity lower than the material constituting the dielectric plug 55. As the material that constitute the connecting portion 70, mention can be made to inorganic materials such as metal, carbon, and conductive ceramic. Thus, in one embodiment, the connecting portion 70 comprises metal, carbon, conductive ceramic, or a composite material of two or more of them. Composite material of metal and ceramic can also be mentioned. As the metal, mention can be made to a simple metal selected from Au, Ag, Al, Ti, and Mo, or an alloy containing one or more of them, stainless steel such as SUS316L, highly corrosion-resistant Ni alloys such as Hastelloy, and steel, and the like. As the carbon, mention can be made to diamond-like carbon (DLC), and the like. As the conductive ceramic, mention can be made to SiC, SiSiC, or the like. When the connecting portion 70 is a conductive mesh, the mesh size may be 0.062 mm (250 mesh) to 0.154 mm (100 mesh). When the connecting portion 70 is a mass of conductive fibers, examples of the material include steel wool, carbon felt, Ti fibers, and porous metal obtained by sintering Al powder. When the connecting portion 70 is a conductive porous body, the porosity thereof can be, for example, 10 to 80% when measured by mercury porosimetry method in accordance with JIS R1655: 2003.

It is preferable that the connecting portion 70 be made of a material having elasticity. For example, the conductive mesh and the mass of conductive fiber described above are also examples of the material having elasticity. When the connecting portion 70 has a directional property in elasticity, it is preferable that the connecting portion 70 has elasticity at least in the vertical direction. It is preferable that the connecting portion 70 be compressed by pressure of the first film 56 on the lower surface 55a of the dielectric plug 55. In this embodiment, the connecting portion 70 is an elastic member, and the connecting portion 70 is compressed vertically between the dielectric plug 55 and the base plate 30 by pressure of the first film 56 on the lower surface 55a of the dielectric plug 55. As the member having elasticity in the vertical direction, an elastic body such as a spring (for example, a coil spring) can also be used. As it is an elastic body, when it is compressed by pressure of the first film 56 on the lower surface 55a of the dielectric plug 55, it has the effect of pushing up the lower surface 55a of the dielectric plug 55, thereby enabling the connecting portion 70 to be reliably brought into contact with the first film 56 provided on the lower surface 55a of the dielectric plug 55. In addition, in the case where the second film 57 is provided on the lower surface 23 of the ceramic substrate 20, it may be compressed by pressure of the second film 57 on the lower surface 23 of the ceramic substrate 20. In this case, however, in order to exert the effect of suppressing discharge, it is necessary that the first film 56 provided on the lower surface 55a of the dielectric plug 55 and the second film 57 provided on the lower surface 23 of the ceramic substrate 20 are in contact with each other. In this case, the connecting portion 70 does not need to be in direct contact with the first film 56. This is because the connecting portion 70 is electrically connected to the first film 56 via the second film 57.

In the above-described embodiment, lift pin holes penetrating the member 10 for a semiconductor manufacturing equipment may be provided. The lift pin holes are holes for inserting lift pins that move the wafer W up and down relative to the upper surface 21 of the ceramic substrate 20. When the wafer W is supported by, for example, three lift pins, three lift pin holes are provided.

The member for a semiconductor manufacturing equipment according to the embodiments described above in detail have the effect of suppressing discharge occurring between the wafer and the base plate, in particular, discharge occurring near the bonding portion between the ceramic substrate and the base plate in the gas passage portion that vertically penetrates the ceramic substrate. For example, the radio frequency (RF) power source connected to the base plate can be made high power. In addition, there is a demand for increasing the gas pressure of the backside gas in order to improve the efficiency of thermal conduction between the wafer and the ceramic substrate, but generally, increasing the gas pressure makes discharge more likely to occur. However, in the member 10 for a semiconductor manufacturing equipment according to the present embodiments, discharge is less likely to occur even when the gas pressure is increased.

### 2. How to Use a Member for Semiconductor Manufacturing Equipment

Next, a method of using the member 10 for a semiconductor manufacturing equipment configured in this way will be exemplified. First, a wafer W is placed on the upper surface 21 of the ceramic substrate 20 with the member 10 for a semiconductor manufacturing equipment installed in a chamber (not shown). Then, the pressure inside the chamber is reduced with a vacuum pump and adjusted to the desired degree of vacuum, and a voltage is applied to the electrode 22 of the ceramic substrate 20 to generate electrostatic adsorption force, and the wafer W is adsorbed and fixed to the wafer placement surface (specifically, the upper surface of the seal band 21a and the upper surface of the small protrusion 21b).

Next, the inside of the chamber is set to a reaction gas atmosphere at a predetermined pressure (for example, several tens to several hundreds of Pa), and in this state, a high frequency voltage such as an RF voltage is applied between an upper electrode (not shown) provided on the ceiling of the chamber and the base plate 30 of the member 10 for a semiconductor manufacturing equipment to generate plasma. The surface of the wafer W is processed by the generated plasma. A refrigerant circulates in the refrigerant passage 32 of the base plate 30. Backside gas is introduced into the gas introduction portion 63b of the gas passage 60 from a gas cylinder (not shown). A thermally conductive gas (for example, He gas or the like) can be used as the backside gas. The backside gas introduced into the gas introduction portion 63b passes through the ring portion 63a and the gas distribution path 62 and is distributed to the plurality of the plug placement holes 50, and is supplied to and sealed in the space between the back surface of the wafer W and the reference surface 21c of the wafer placement surface. The presence of this backside gas allows efficient heat conduction between the wafer W and the ceramic substrate 20.

Further, by providing the dielectric plug 55 in the plug placement hole 50, electric discharge within the plug placement hole 50 can be suppressed. If there is no dielectric plug 55, electrons generated as gas molecules are ionized by the application of RF voltage are accelerated and collide with other gas molecules, causing glow discharge and eventually arc discharge. However, when the dielectric plug 55 is present, the electrons hit the dielectric plug 55 before colliding with the other gas molecules, so that discharge is suppressed.

### 3. Method for Manufacturing a Member for Semiconductor Manufacturing Equipment

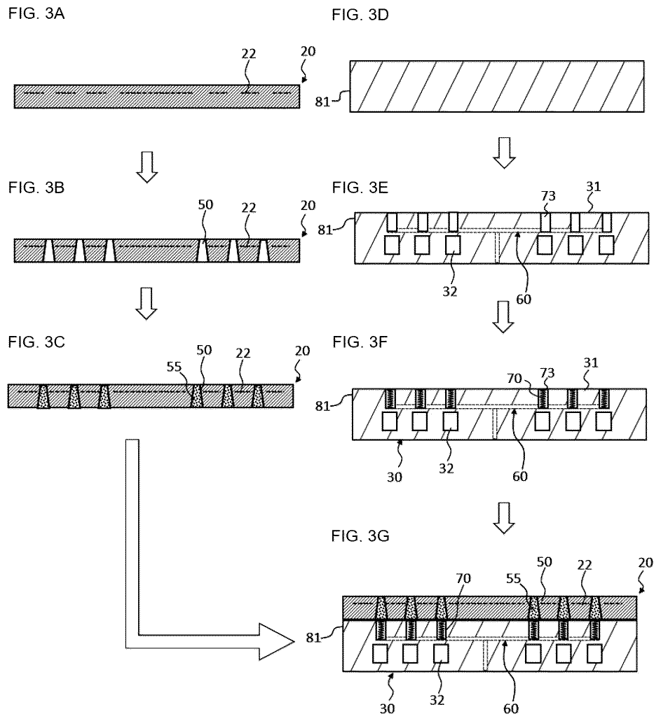

Next, a method for manufacturing the member 10 for a semiconductor manufacturing equipment will be exemplarily described based on FIGS. 3A to 3G. FIGS. 3A to 3G are manufacturing process diagrams of the member 10 for a semiconductor manufacturing equipment according to an embodiment of the present invention. Here, a case where the base plate 30 is made of MMC will be illustrated as an example. First, a ceramic substrate 20 having an electrode 22 therein is prepared (FIG. 3A). The ceramic substrate 20 is prepared as follows. A ceramic formed body having an internal electrode 22 is prepared. The ceramic formed body may be manufactured by laminating a plurality of tape formed bodies, by a mold casting method, or by compacting ceramic powder. Next, the ceramic formed body is hot-pressed and fired to obtain the ceramic substrate 20. Subsequently, the plug placement hole 50 is formed in the ceramic substrate 20 (FIG. 3B). The plug placement hole 50 is formed to vertically penetrate the ceramic substrate 20 while avoiding the electrode 22.

Next, the dielectric plug 55 is embedded in the plug placement hole 50 (FIG. 3C). As a method for embedding the dielectric plug 55 in the plug placement hole 50, for example, a method in which the dielectric plug 55 formed in advance by firing or the like is press-fitted into the plug placement hole 50 can be mentioned. Alternatively, the dielectric plug 55 may be installed by forming a male threaded portion on the outer peripheral surface of the dielectric plug 55 which has been formed in advance by firing or the like, forming a female threaded portion on the inner peripheral surface of the plug placement hole 50, inserting the dielectric plug 55 into the plug placement hole 50 by screwing the male threaded portion of the dielectric plug 55 into the female threaded portion of the plug placement hole 50. Furthermore, the dielectric plug 55 may be formed by injecting a paste-like ceramic mixture, which serves as a precursor of the dielectric plug 55, into the plug placement hole 50 in the ceramic substrate 20 and firing it. As described above, the method for covering the lower surface 55a of the dielectric plug 55 with the first film 56 includes a sputtering method and the like. The first film 56 may be formed before or after the dielectric plug 55 is embedded in the plug placement hole 50.

Apart from the ceramic substrate 20, a metallic disk member 81 is prepared (FIG. 3D). Then, grooves and holes for the gas passage 60 and the refrigerant passage 32 are appropriately formed in the metallic disk member 81 by machining (FIG. 3E).

Next, the conductive connecting portion 70 is inserted into the through hole 73 which becomes the gas distribution path 62 (FIG. 3F). In this case, for example, before contact with the first film 56 covering the lower surface 55a of the dielectric plug 55 (before the connecting portion 70 is compressed), it is preferable to position the connecting portion 70 such that the upper end 70a of the connecting portion 70 protrudes above the upper surface 31 of the base plate 30. In this way, it is easy to press the connecting portion 70 when the connecting portion 70 is brought into contact with the first film 56.

Next, the upper surface 31 of the base plate 30 and the lower surface of the ceramic substrate 20 are bonded together with a thermosetting resin adhesive sheet (FIG. 3G). A method for bonding the upper surface 31 of the base plate 30 and the lower surface of the ceramic substrate 20 together with a thermosetting resin adhesive sheet will now be described in detail. First, a thermosetting resin adhesive sheet having adhesive layer penetrating portions at predetermined positions is attached to the upper surface 31 of the base plate 30, and then the ceramic substrate 20 is placed on it. This laminate is heated and pressurized in an autoclave to cure the thermosetting resin adhesive sheet whereby the bonding is finished.

Thereafter, the member 10 for a semiconductor manufacturing equipment is completed by appropriately going through processes such as adjusting the overall shape.

### DESCRIPTION OF REFERENCE NUMERALS

10: Member for semiconductor manufacturing equipment
20: Ceramic substrate
21: Upper surface
21a: Seal band
21b: Small protrusion
21c: Reference surface
22: Electrode
23: Lower surface
30: Base plate
31: Upper surface
31a: Inner periphery
32: Refrigerant passage
33: Lower surface
40: Resin adhesive layer
41: Lower surface
42: Upper surface
50: Plug placement hole
50a: Inner periphery
55: Dielectric plug
55a: Lower surface
55b: Outer peripheral surface
55c: Gas passage portion
55d: Upper surface
56: First film
57: Second film
56a: Outer periphery
60: Gas passage
62: Gas distribution path
62a: Bottom surface
63: Gas supply path
63a: Ring portion
63b: Gas introduction portion
64: Adhesive layer penetrating portion
64a: Inner periphery
64b: location with smallest opening diameter
70: Connecting portion
70a: Upper end
70b: Lower end
73: Through hole
81: Disk member

1. A member for a semiconductor manufacturing equipment, comprising:
a ceramic substrate comprising an upper surface on which a wafer is to be placed, and a lower surface opposite to the upper surface,
a plug placement hole that vertically penetrates the ceramic substrate,
a dielectric plug embedded in the plug placement hole, the dielectric plug comprising a lower surface and a gas passage portion penetrating the dielectric plug,
a first film covering at least a part of the lower surface of the dielectric plug and made of a material having a volume resistivity lower than that of a material constituting the dielectric plug,
a conductive base plate bonded to the lower surface of the ceramic substrate via a resin adhesive layer,
a gas passage that passes through the base plate and the resin adhesive layer to supply gas to the gas passage portion of the dielectric plug, and
a conductive connecting portion provided in the gas passage, the conductive connecting portion comprising an upper end electrically connected to the first film and a lower end electrically connected to the base plate;
wherein at least a part of the first film is in contact with the resin adhesive layer, and/or at least a part of the lower surface of the ceramic substrate is covered with a second film made of a material having a volume resistivity lower than that of a material constituting the ceramic substrate, and at least a part of the second film is in contact with the resin adhesive layer and also in contact with the first film.

2. The member for a semiconductor manufacturing equipment according to claim 1, wherein at least a part of the first film is in contact with the resin adhesive layer.

3. The member for a semiconductor manufacturing equipment according to claim 1, wherein at least a part of the lower surface of the ceramic substrate is covered with the second film made of a material having a volume resistivity lower than that of the material constituting the ceramic substrate, and at least a part of the second film is in contact with the resin adhesive layer and also in contact with the first film.

4. The member for a semiconductor manufacturing equipment according to claim 1, wherein the connecting portion comprises a member having elasticity, and the member having elasticity is compressed by pressure of the first film on the lower surface of the dielectric plug.

5. The member for a semiconductor manufacturing equipment according to claim 1, wherein the connecting portion comprises a member having elasticity, and the member having elasticity is compressed by pressure of the second film on the lower surface of the ceramic substrate.

6. The member for a semiconductor manufacturing equipment according to claim 1, wherein the material constituting the dielectric plug and the material constituting the ceramic substrate each contain one or more selected from aluminum oxide, aluminum nitride, quartz, and zirconia.

7. The member for a semiconductor manufacturing equipment according to claim 1, wherein the first film on the lower surface of the dielectric plug comprises metal, carbon, conductive ceramic, or a composite material containing two or more of them.

8. The member for a semiconductor manufacturing equipment according to claim 1, wherein the second film on the lower surface of the ceramic substrate comprises metal, carbon, conductive ceramic, or a composite material of two or more of them.

9. The member for a semiconductor manufacturing equipment according to claim 1, wherein the dielectric plug is an inorganic dielectric plug having a dense outer peripheral surface, and is embedded in the plug placement hole such that the outer peripheral surface directly fits an inner peripheral surface of the plug placement hole.

10. The member for a semiconductor manufacturing equipment according to claim 1, wherein an inner periphery of a penetrated portion of the resin adhesive layer that defines the gas passage is configured such that the gas passage becomes wider upward.

11. The member for a semiconductor manufacturing equipment according to claim 9, wherein the inner peripheral surface of the plug placement hole that fits the dense outer peripheral surface of the dielectric plug is dense.
